(19) United States
(12) Patent Application Publication
(10) Pub. No.: US 2007/0103957 A1
(43) Pub. Date: May 10, 2007

(54) Data transfer in a memory device

(76) Inventors: Roland Barth, Munchen (DE); Peter Gregorius, Munchen (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/590,488

(22) Filed: Oct. 30, 2006

(30) Foreign Application Priority Data
Oct. 28, 2005 (DE) 10 2005 051 792.7

(51) Int. Cl. G11C 5/06

(52) U.S. Cl. 365/63

(57) ABSTRACT

A method transfers data in a memory device including at least one memory module and a memory controller. The method includes coupling the memory module to the memory controller via a mechanically detachable data transfer connection, transferring data between the memory controller and an interface unit assigned to the memory module and disposed on the same side of the mechanically detachable data transfer connection as the memory controller, and transferring data between the interface unit and the memory module via the mechanically detachable data transfer connection.

### CROSS-REFERENCE TO RELATED APPLICATIONS

This Utility Patent Application claims priority to German Patent Application No. DE 10 2005 051 792.7, filed on Oct. 28, 2005, which is incorporated herein by reference.

### BACKGROUND

Conventional computer systems include read/write memories (e.g., random access memory (RAM) in the form of memory modules. The read/write memories each have a plurality of memory modules in corresponding receptacles of a system board. The memory modules are electrically coupled (e.g., via a plug-in connection) to a memory controller provided on the system board. A processor, such as a central processing unit (CPU), of the computer system, or further system components, are then connected to the memory modules via the memory controller.

If a plurality of memory modules are used, it is known for these modules to be connected to one another in a chain-type arrangement, such that a first memory module of the chain-type arrangement is directly coupled to the memory controller, while the remaining memory modules of the chain-type arrangement effect the transfer of data with the memory controller via the first memory module of the chain-type arrangement. Specifically, command data or write data may be transmitted, starting from the first memory module of the chain-type arrangement, from one of the memory modules to the next memory module of the chain-type arrangement, until the data are received in a final memory module of the chain-type arrangement. Conversely, read data are transmitted from a memory module of the chain-type arrangement to the preceding memory module of the chain-type arrangement, until the data are received in the first memory module of the chain-type arrangement. The first memory module of the chain-type arrangement receives the write or command data from the memory controller and transmits the read data to the memory controller.

In order to realize mutual communication between the memory modules, the memory modules each comprise an interface component which has transmit and receive structures for transferring the respective data signals. In the case of fully-buffered type of memory modules, a serial high-speed protocol may be used for the transfer of data.

FIG. 1 illustrates an example memory device having a plurality of fully-buffered type memory modules, according to the above-mentioned type. The memory device comprises a plurality of memory modules 100a′, 100b′, 100c′ and a memory controller 200′. The memory controller 200′ is located on the system board of a computer system and is implemented, for example, in a north bridge. The memory controller 200′ sends a command data signal CA or a write data signal WD to the memory modules 100a′, 100b′, 100c′. Conversely, the memory controller 200′ receives a read data signal RD from the memory modules 100a′, 100b′, 100c′. The transfer of data according to the serial high-speed protocol is based on a clock signal CLK′, which is transmitted from the memory controller to the memory modules 100a′, 100b′, 100c′.

The memory modules 100a′, 100b′, 100c′ are each connected to the system board of the computer system via a plug-in connection 10′, in order thereby to provide for an electrical connection to the memory controller 200′. In FIG. 1, the plug-in connections 10′ are indicated by continuous lines.

Each of the memory modules comprises a plurality of memory chips or memory components 110′, as well as an interface chip or interface component 150′ which effects the transfer of data to the memory controller 200′ and to adjacent memory modules 100a′, 100b′, 100c′ of the chain-type arrangement.

Specifically, the interface component 150′ of the first memory module 100a′ of the chain-type arrangement receives the command data signal or write data signal CA, WD from the memory controller. Starting from the interface component 150′ of the first memory module 100a′, the write or command data signal CA, WD is transmitted to the interface component 150′ of the respectively next memory module 100b′, 100c′ of the chain-type arrangement, until the signal is received in the interface component 150′ of the final memory module 100c′ of the chain-type arrangement. Conversely, the read data signal RD is transmitted, starting from the interface component 150′ of the final memory module 100c′ of the chain-type arrangement, to the interface component 150′ of the respectively preceding memory module 100a′, 100b′ of the chain-type arrangement, until the signal is finally received in the interface component 150′ of the first memory module 100a′ of the chain-type arrangement. As already mentioned, the read data signal RD is transmitted from the interface component 150′ of the interface component of the first memory module 100a′ of the chain-type arrangement to the memory controller 200′.

In order to effect the transfer of data according to the principle described above, the interface components of the memory modules 100a′, 100b′, 100c′ each receive the clock signal CLK′ from the memory controller 200′, in order to transmit the data signals based on this clock signal CLK′ and to sample the received data signals based on the clock signal CLK′.

As illustrated by FIG. 1, a communication channel between the memory controller 200′ and the individual memory modules 100a′, 100b′, 100c′ passes via a plurality of plug-in connections. Particularly in the case of high data rates (i.e., when a high frequency is used for the clock signal CLK′) there typically ensue substantial losses in quality in the transmitted data signals and also in the transmitted clock signal CLK′, such that reliable transfer of data is typically no longer possible. Some reasons for this include, inter alia, reflections or crosstalk at the plug-in connections.

For these and other reasons, there is a need for the present invention.

### SUMMARY

One embodiment provides a method of transferring data in a memory device including at least one memory module and a memory controller. The method includes coupling the memory module to the memory controller via a mechanically detachable data transfer connection. The method includes transferring data between the memory controller and an interface unit assigned to the memory module and disposed on the same side of the mechanically detachable data transfer connection as the memory controller. The method includes transferring data between the interface unit and the memory module via the mechanically detachable data transfer connection.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates an example memory device.

FIG. 2 illustrates a memory device according to one embodiment.

FIG. 3 illustrates a memory device according to one embodiment.

FIG. 4 illustrates a memory device according to one embodiment.

FIG. 5 illustrates a memory device according to one embodiment.

FIG. 6 illustrates a memory device according to one embodiment.

FIG. 7 illustrates a memory device according to one embodiment.

FIG. 8 illustrates, in schematic form, one embodiment of a structure of an interface unit for use in the memory device according to the embodiment illustrated in FIG. 2.

FIG. 9 illustrates, in schematic form, one embodiment of a structure of an interface unit for use in the memory device according to the embodiment illustrated in FIG. 3.

FIG. 10 illustrates, in schematic form, one embodiment of a structure of an interface unit for use in the memory device according to the embodiment illustrated in FIG. 4.

FIG. 11 illustrates, in schematic form, one embodiment of a structure of an interface unit for use in the memory device according to the embodiment illustrated in FIG. 5.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Embodiments relate to the transfer of data in a memory device, between a memory module and a memory controller, the memory module being electrically coupled to the memory controller via a mechanically detachable connection. Specifically, embodiments relate to a method of accomplishing the transfer of data in such a memory device, to a device for coupling at least one memory module to a memory controller via a mechanically detachable connection (e.g., a plug-in connection), and to a correspondingly designed memory module.

One embodiment of a memory device includes a memory controller and at least one memory module, which are coupled to each other via a mechanically detachable data transfer connection to assign to the memory module an interface unit which is disposed, not on the memory module, but on the same side of a mechanically detachable connection as the memory controller. The mechanically detachable connection may be a plug-in connection. Other embodiments include other suitable types of mechanically detachable connection (e.g., a clamped connection).

One embodiment of a method of transferring data in a memory device having a memory controller and at least one memory module that is electrically coupled to the memory controller via the mechanically detachable connection, comprises transferring data between the memory controller and an interface unit which is assigned to the memory module and is disposed on the same side of the mechanically detachable connection as the memory controller, and transferring data between the interface unit and the memory module via the mechanically detachable connection.

Consequently, in one embodiment, the transfer of data between the memory controller and the interface unit is no longer effected via the mechanically detachable connection, and can thus be optimized with respect to the signal transmission characteristics. In certain embodiments, the communication channel between the interface unit and the memory module, passing via the mechanically detachable connection, is however less critical with respect to its signal transmission characteristics. This becomes clear particularly when the memory device comprises a plurality of the memory modules, a respective interface unit being assigned in this case to each of the memory modules. In order to provide a communication channel to the individual memory modules, in this case data are also transferred between the individual interface units. The communication channel between the memory controller and the interface units, and between the individual interface units, thus carries not only the data for one of the memory modules, but the totality of the data transferred between the memory controller and the memory modules, such that there is transferred between the memory controller and the interface units, and between the individual interface units, a quantity of data which is a multiple of that transferred between one of the memory modules and the associated interface unit via the mechanically detachable connection. Consequently, through use of the above-mentioned approach according to embodiments, a substantial enhancement of performance can be achieved by optimization of the signal transfer characteristics of the communication channel between the memory controller and the interface units.

According to one embodiment, the interface units are coupled to one another in a series arrangement, and different configurations are possible for the transfer of data within the series arrangement.

For example, a command or write data signal from the memory controller can be received in a first interface unit of the series arrangement and then, starting from the first interface unit, be transmitted from one of the interface units to the respectively next interface unit of the series arrangement, until the command or write data signal has been received in a final interface unit of the series arrangement.

Alternatively, the command or write data signal can be transmitted in a star-type fashion from the first interface unit of the series arrangement to a plurality of further interface units. In this case there is the possibility, on the one hand, of transmitting the command or write data signal, starting from the first interface unit, to all other interface units, or, starting from the further interface units to which the command data signal or write data signal was transmitted starting from the first interface unit, of transmitting the command data signal or write data signal from an interface unit to the respectively next interface unit of an adjoining chain-type arrangement.

As compared with the use of a purely chain-type arrangement for transmitting the command or write data signal, a shorter latency time is achieved through transmitting the command or write data signal in a star-type fashion.

With regard to the transfer of a read data signal, there is first of all the possibility of transmitting the read data signal from one of the interface units to the respectively preceding interface unit of the series arrangement, until the read data signal has been received in the first interface unit of the series arrangement, and of then transmitting the read data signal from the first interface unit to the memory controller. This corresponds to a reverse loop configuration, in which the read data signal is transferred between the interface units in the direction which is essentially the reverse of that of the command or write data signal.

Alternatively, it is possible for the read data signal to be transmitted from one of the interface units to the respectively next interface unit of the series arrangement, until the read data signal has been received in a final interface unit of the series arrangement, and for the read data signal then to be transmitted from the final interface unit to the memory controller. This corresponds to a forward loop configuration, in which the read data signal is transmitted between the interface unit in essentially the same direction as the command or write data signal. The forward loop configuration offers advantages in that, in particular, the latency time for accesses to a memory module is dependent only to a small extent on the position, in the series arrangement, of the interface unit assigned to the memory module. In particular, with increasing distance of the interface unit from the memory controller, an extended transmission path for the command or write data signal is compensated by a shortened transmission path for the read data signal to the memory controller.

With regard to the clock data signals on the basis of which the above-mentioned data signals (i.e., the command or write data signal or the read data signal) are sent out, or on the basis of which the received data signals are sampled, it is possible to use, on the one hand, a source-synchronous arrangement, in which clock signals assigned to the data signals are transmitted in parallel to the latter between the memory controller and the interface units, and between the interface units. On the other hand, it is possible to use a mesosynchronous arrangement, in which a reference clock signal is supplied from a central reference clock-signal source to each of the interface units and to the memory controller. The clock signals assigned to the data signals may be generated and conditioned in the interface units with a phase locked loop. It is thereby ensured that the transfer of data is effected on the basis of a high-quality clock signal, thereby ensuring increased reliability and providing for higher data rates.

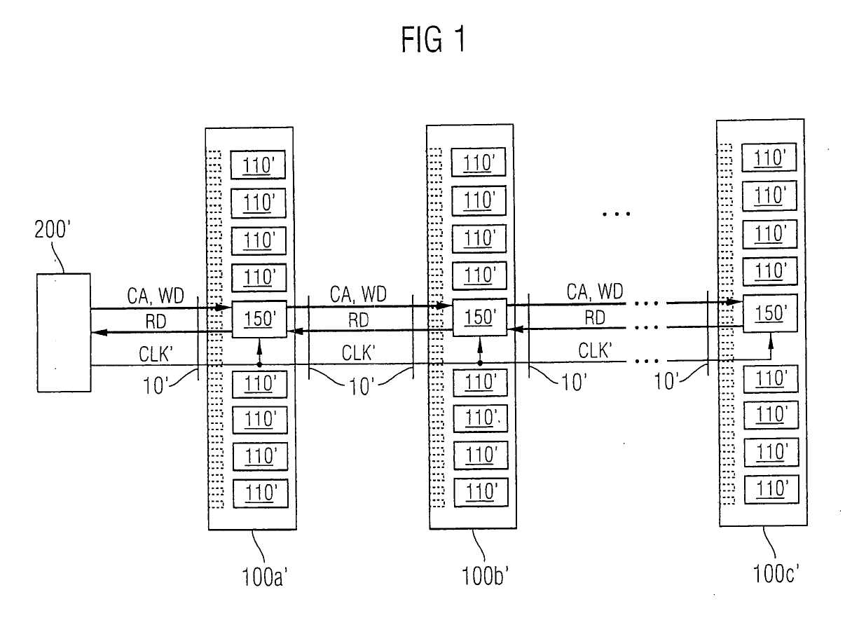

One embodiment of a memory module is configured to be used within the above-described method embodiment. One memory module embodiment is configured to be coupled to a memory controller of the memory device by means of a mechanically detachable connection for the transmission of data. The memory module is additionally configured to receive data from an external interface unit, and to transmit data to the external interface unit, via the mechanically detachable connection. In contrast to the memory modules as described with reference to FIG. 1, one memory module embodiment does not need an internal interface component that effects communication with further memory modules or with the memory controller.

According to one embodiment, the memory module comprises at least one memory component (e.g., a memory chip) which can be directly coupled to the external interface unit via the mechanically detachable connection. Further memory components of the memory module can then be coupled to the interface unit via this memory component.

One embodiment of a device is configured to couple at least one memory module to a memory controller via a mechanically detachable data transfer connection. The device comprises at least one interface unit which is disposed on the same side of the mechanically detachable connection as the memory controller. A plurality of interface units may be provided, in dependence on the provided number of memory modules that can be coupled to the memory controller by means of the device. The at least one interface unit, or the interface units, is/are coupled to the memory controller for the purpose of data transfer, and can be coupled to the memory module or the memory modules via the mechanically detachable connection for the purpose of data transfer.

In one embodiment, the device may be combined with one or more memory modules of the above-mentioned type in order to constitute a memory device that is configured to operate according to the principles as explained above.

Explained in the following are various examples of embodiments of memory devices in which a plurality of memory modules are coupled to a memory controller via a mechanically detachable data transfer connection. The mechanically detachable connection may be, specifically, a plug-in connection. Also possible, however, are other suitable types of mechanically detachable connection (e.g., a clamped connection).

For the provision of the mechanically detachable connection, the embodiments of the memory modules described in the following comprise a plurality of contact surfaces which are disposed along one side of a printed circuit board of the memory module. Upon insertion of the memory module into a receptacle of a system board of a computer system, the receptacle being provided for this purpose, the contact surfaces are brought into engagement with corresponding mating contacts on the system board, such that an electrically conductive connection is produced. In one embodiment, the memory modules are each equipped with a plurality of memory components or memory chips, which may be, for example, dynamic random access memories (DRAMs) of the double data-rate type (DDR) type.

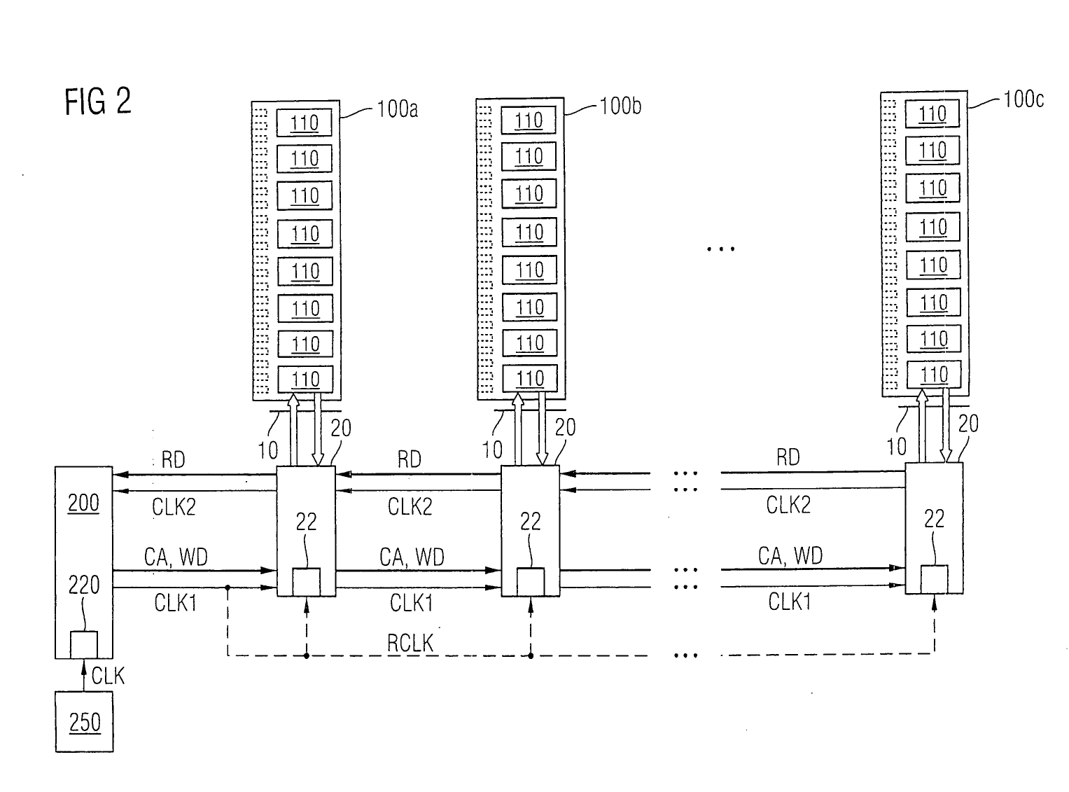

FIG. 2 illustrates a memory device according to one exemplary embodiment. The memory device comprises a plurality of memory modules 100a, 110b, 100c, each of which is coupled to a memory controller 200 via a mechanically detachable data transfer connection 10. The memory modules 100a, 110b, 100c are each provided with a plurality of memory components 110.

The memory controller 200 is disposed on a system board of a computer system, and serves to connect the memory modules to a processor of the computer system and to further system components.

The memory device furthermore comprises a plurality of interface units 20, which are likewise disposed on the system board of the computer system and which are respectively assigned to one of the memory modules 100a, 100b, 100c. A respective bidirectional interface via the mechanically detachable connection 10 is provided between the memory modules 100a, 100b, 100c and the interface units 20 assigned thereto. The memory device thus comprises a first part, which is disposed on the system board of the computer system and comprises the memory controller 200 and the interface units 20, and a second part, which is constituted by the memory modules 100a, 100b, 100c. In one embodiment, the mechanically detachable connections 10 provide for a modular design of the memory device, whereby memory modules can be easily replaced, added or removed.

Additionally provided, as a clock generating unit, on the system board is a phase locked loop 250, which provides a main clock signal CLK for the memory controller 200. According to one embodiment, the phase locked loop 250 is digitally implemented, such that a high signal quality can be achieved for the main clock signal with a small amount of circuitry resource. Furthermore, in one embodiment the digital design of the phase locked loop 250 provides for good capability for combination with further digital components of the computer system.

The interface units 20 are coupled, in a series arrangement, to the memory controller 200. Specifically, a chain-type arrangement is provided, in which data are transferred between respectively adjacent interface units 20.

A first interface unit 20 of the series arrangement receives a command or write data signal CA, WD from the memory controller 200. Starting from the first interface unit 20 of the series arrangement, the command or write data signal is transmitted from one interface unit 20 to the respectively next interface unit 20 of the series arrangement, until the command or write data signal CA, WD is received in the final interface unit 20 of the series arrangement 20.

A read data signal RD is transmitted, in the reverse direction, from one of the interface units 20 to the respectively preceding interface unit 20 of the series arrangement, until the read data signal RD is finally received in the first interface unit 20 of the series arrangement. From the first interface unit of the series arrangement, the read data signal RD is transmitted to the memory controller 200.

The interface units 20 are thus coupled to one another in a forward loop configuration.

Bidirectional transmission of data is effected between the interface units 20 and the memory modules 100a, 100b, 100c via the mechanically detachable connection 10, but with only data addressed to the respective memory module 100a, 100b, 100c, or data originating from the respective memory module 100a, 100b, 100c, being transferred. Consequently, the quantities of data transferred between the interface units 20 and the memory modules 100a, 100b, 100c via the mechanically detachable connection 10 are generally substantially less than those that are transferred between the memory controller 200 and the interface units 20 or between the interface units 20. In one embodiment, since the memory controller 200 and the interface units 20 are disposed all together on the system board of the computer system, and the system connections that exist between them therefore do not pass via the mechanically detachable connections 10, these signal connections can be optimized with respect to their signal transmission characteristics, with impairments of the signal quality resulting from reflection or crosstalk at the mechanically detachable connections being prevented at the same time.

The transfer of data between the memory controller 200 and the interface units 20 is based on a serial high-speed protocol. In this case, provision is made for data to be transmitted from a transmitter based on a clock signal, and sampled at a receiver based on a clock signal. The memory device of FIG. 1 provides, in this respect, for a source-synchronous transfer of data. This means that, in parallel to the transmitted data signal, an associated clock signal is transmitted from the transmitter to the receiver. This clock signal is the clock signal on the basis of which the data signal was transmitted at the transmitter. In the receiver, the received data signal is sampled based on the associated clock signal.

In the case of the memory device illustrated in FIG. 2, an associated clock signal CLK1 is transmitted in parallel to the command and write data signal CA, WD. An associated clock signal CLK2 is transmitted in parallel to the read data signal RD. In addition, a reference clock signal RCLK can be transmitted to the interface units 20, as indicated by arrows represented by broken lines. The reference clock signal RCLK is derived from the associated clock signal CLK1 of the command or write data signal CA, WD transmitted between the memory controller 200 and the first interface unit 20 of the series arrangement.

The interface units 20 each comprise a phase locked loop 22, and the memory controller 200 comprises a phase locked loop 220. As explained more fully in the following, the phase locked loops 22, 220 serve to condition an input clock signal and to generate output clock signals of a high signal quality, on the basis of which the transmission of data is then effected. In this way, in embodiments, the reliability of the data transfer is substantially improved, and higher data rates are rendered possible.

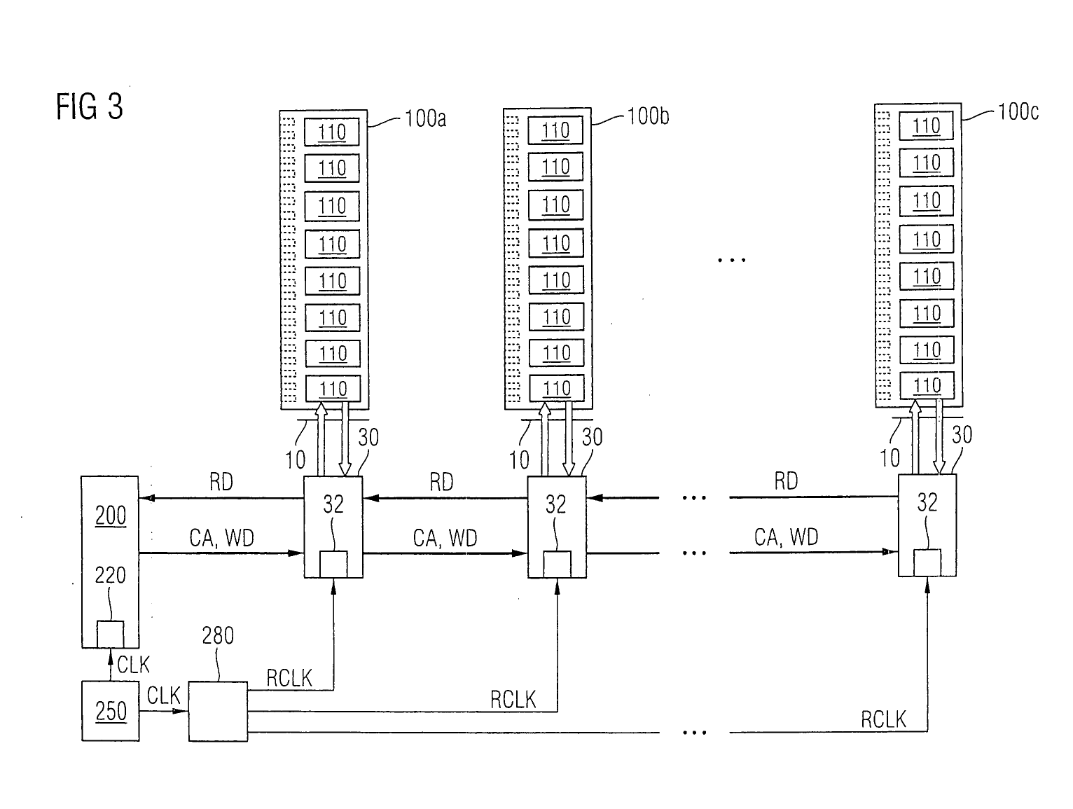

FIG. 3 illustrates a memory device according to one exemplary embodiment. The structure of the memory device embodiment of FIG. 3 corresponds, in essence, to that of FIG. 2. In FIG. 3, components which correspond to those of FIG. 2 have been denoted by the same reference signs, and they are not explained further in the following.

In the memory device embodiment of FIG. 3, the interface units 20 of FIG. 2 have been replaced by interface units 30, which are configured for a mesosynchronous transfer of data. This means that the clock signal on the basis of which the data signal is transmitted at the transmitter, and the clock signal with which the data signal received in the receiver is sampled, are generated on the basis of an externally provided reference clock signal RCLK. In this embodiment, transmission of a clock signal associated with the data signal in parallel to the data signal is thus no longer needed, but may be effected in addition as a supplementary transmission.

The reference clock signal RCLK for the interface units 30 is generated by clock replicator 280 based on the main clock signal CLK generated by the phase locked loop 250. An input clock signal of uniformly high quality is thus available to each of the interface units 30 and also to the memory controller 200.

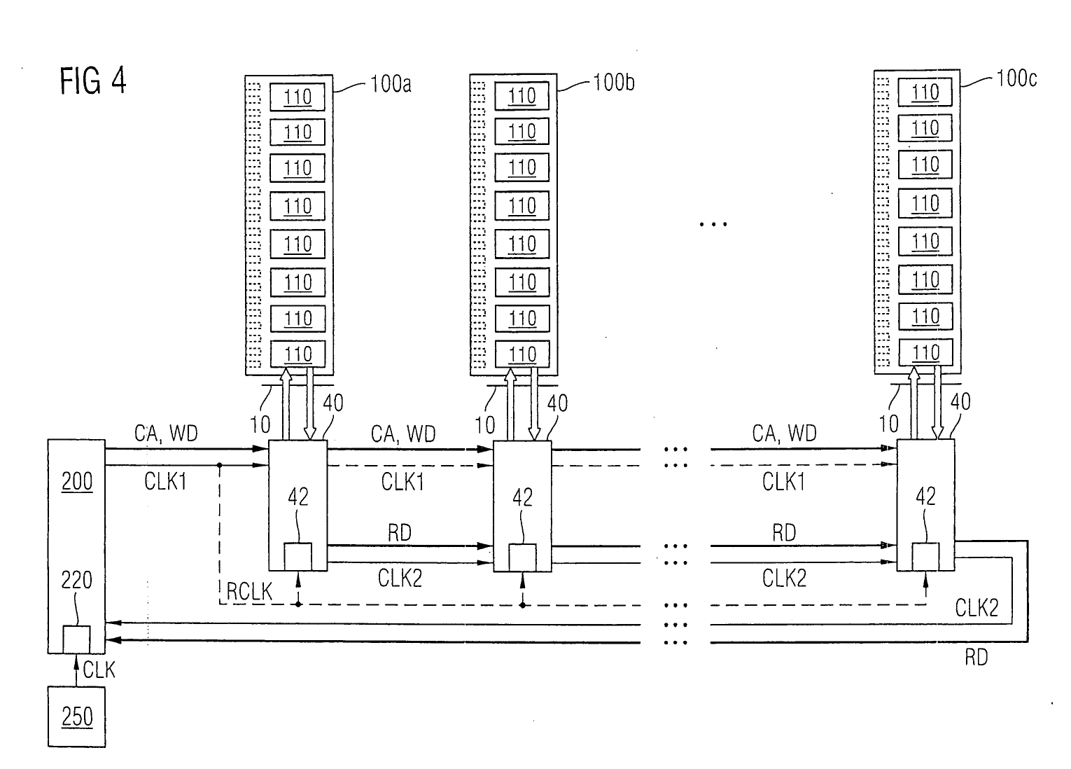

FIG. 4 illustrates a memory device according to one exemplary embodiment. The structure of the memory device embodiment of FIG. 4 corresponds, in essence, to that of the memory device of FIG. 2. In FIG. 4, components which correspond to those of FIG. 2 have been denoted by the same reference signs, and they are not explained further in the following.

In the memory device embodiment of FIG. 4, the interface units 20 of the memory device of FIG. 2 have been replaced by interface units 40, which are configured for a source-synchronous transfer of data according to a forward loop configuration.

This means, specifically, that a first interface unit 40 of the series arrangement receives the command or write data signal CA, WD from the memory controller 200, which data signal is then transmitted from one interface unit 40 to the respectively next interface unit 40 of the series arrangement until it is received in the final interface unit 40 of the series arrangement as already explained in the case of the memory device of FIG. 2. In contrast to the reverse loop configuration provided according to the embodiments of FIGS. 2 and 3, in the forward loop configuration embodiment of FIG. 4 the read data signal RD is transmitted from one interface unit 40 to the respectively next interface unit 40 of the series arrangement in the same direction as that of the command or write data signal CA, WD, until the read data signal is finally received in the final interface unit 40. From the final interface unit 40 of the series arrangement, the read data signal RD is then transmitted to the memory controller 200.

The forward loop configuration embodiment can offer advantages with respect to a latency time that is non-dependent on the position of the interface unit. Thus, for example, the time for transmission of the command or write data signal CA, WD to the first interface unit 40 of the series arrangement is the shortest, while, for this interface unit 40, the time for transmission of the read data signal RD to the memory controller 200 is the longest. In the case of the final interface unit 40 of the series arrangement, on the other hand, the time for transmission of the command or write data signal CA, WD from the memory controller 200 is the longest, while the time for transmission of the read data signal RD to the memory controller 200 is the shortest. Differences in the time for transmission of the data signals resulting from the differing positions of the interface units 40 in the series arrangement are thus compensated.

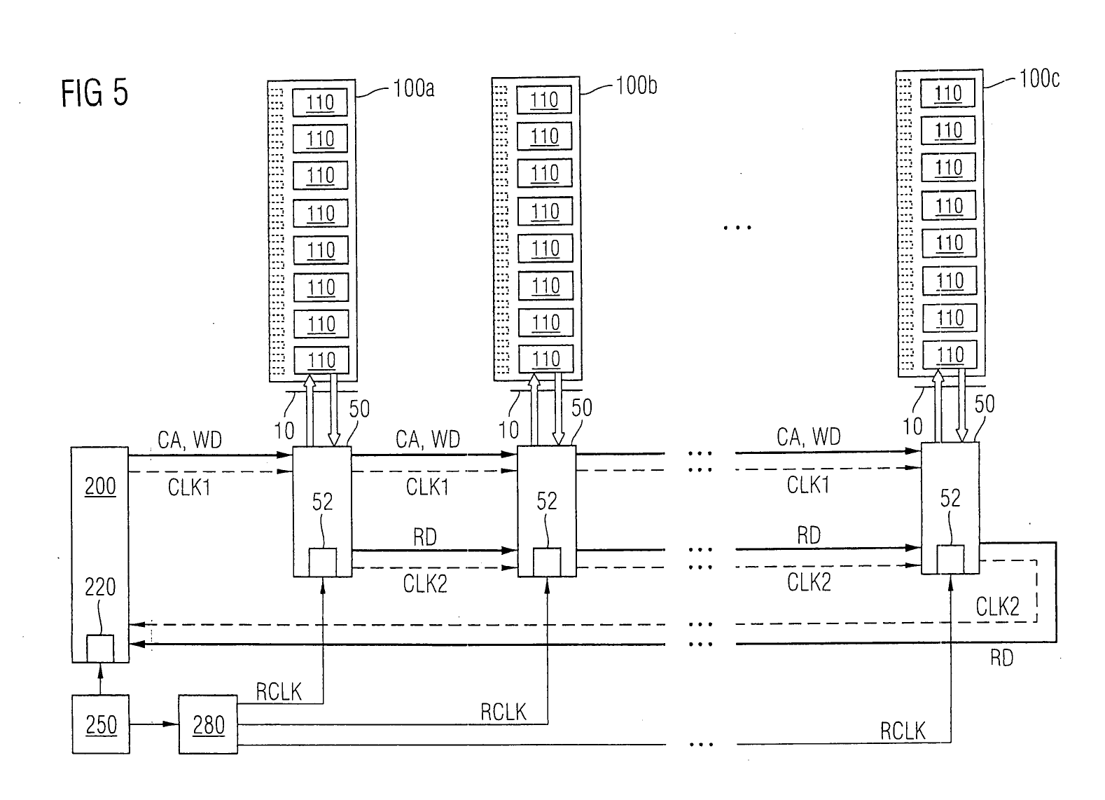

In the memory device embodiment illustrated in FIG. 4, the transfer of data is of the source-synchronous type (i.e., the associated clock signal CKL1 is transmitted in parallel to the command or write data signal CA, WD, and the associated clock signal CLK2 is transmitted in parallel to the read data signal RD). However, the forward loop configuration explained with reference to FIG. 4 can also be used in connection with a mesosynchronous transfer of data, as has been explained with reference to the embodiment of FIG. 3. This is illustrated in FIG. 5.

FIG. 5 illustrates a memory device according to one exemplary embodiment. As already mentioned, the memory device embodiment of FIG. 5 corresponds, in essence, to that of FIG. 4, but with the use of a mesosynchronous transfer of data corresponding to the principle explained with reference to FIG. 3. Accordingly, in the memory device embodiment of FIG. 5, the interface units 40 of the memory device of FIG. 3 have been replaced by interface units 50, which are configured for mesosynchronous transfer of data according to a forward loop configuration. In FIG. 5, components which correspond to those of FIGS. 2-4 are denoted by the same reference signs, and they are not explained further in the following.

Each of the interface units 50 are supplied with the reference clock signal RCLK generated by the clock replicator 280, the reference clock signal being generated centrally based on the main clock signal CLK generated by the phase locked loop 250.

As already mentioned in connection with FIG. 3, in the case of the mesosynchronous transfer of data it is no longer necessary for the associated clock signal CLK1 to be transmitted in parallel to the command or write data signal CA, WD, and for the associated clock signal CLK2 to be transmitted in parallel to the read data signal RD. However, in order to ensure greater flexibility in the selection of clock signals, the associated clock signals CLK1 and CLK2 may nevertheless be transmitted in parallel to the command or write data signal CA, WD, and in parallel to the read data signal RD, respectively. This is indicated in FIG. 5 by arrows represented as broken lines.

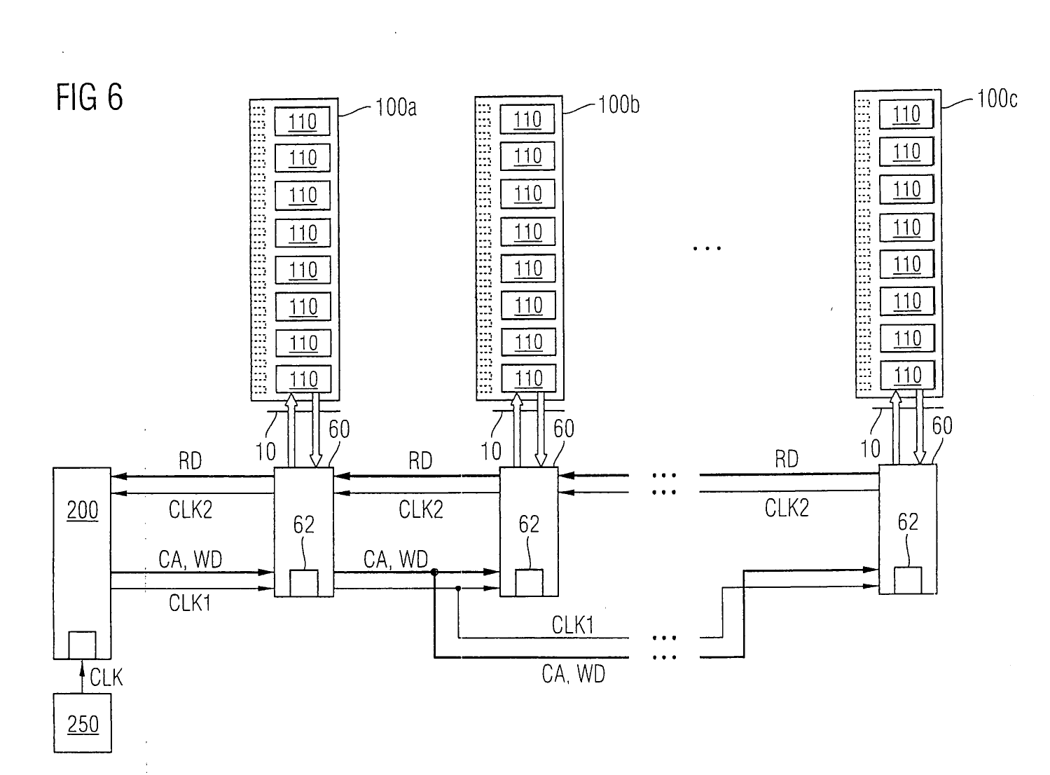

FIG. 6 illustrates a memory device according to one exemplary embodiment. The structure of the memory device embodiment of FIG. 6 corresponds, in essence, to that of the memory device of FIG. 2. In FIG. 6, components which correspond to those of FIG. 2 have been denoted by the same reference signs, and they are not explained further in the following.

In the memory device embodiment of FIG. 6, the interface units 20 of the memory device of FIG. 2 have been replaced by interface units 60, which are designed for a star-type transfer of the command or write data signal CA, WD. In the memory device embodiment of FIG. 6, transmission of the read data signal RD is effected in the same manner as has already been explained in connection with the memory device embodiment of FIG. 2. The command or write data signal CA, WD is however transmitted in a star-type fashion in the memory device embodiment of FIG. 6.

This means, specifically, that the first interface unit 60 of the series arrangement receives the command or write data signal CA, WD from the memory controller 200, the command or write data signal CA, WD then being transmitted, starting from the first interface unit 60 of the series arrangement, to the other interface units 60. In this case it is possible, on the one hand, for the command or write data signal CA, WD to be transmitted, starting from the first interface unit 60, to all other interface units 60 of the series arrangement. On the other hand it is also possible, starting from the further interface units 60 in which the command or write data signal CA, WD was received from the first interface unit 60 of the series arrangement, to transmit the command or write data signal CA, WD in a chain-type or star-type fashion to further interface units 60. In one embodiment, it is thereby possible to avoid a high number of connections emanating from a single point in the star-type connection.

Compared with a purely chain-type transfer of data, such as that described, for example, with reference to the embodiment of FIG. 2, the star-type transfer of data in the memory device embodiment of FIG. 6 renders possible a reduced time for the transmission of the command or write data signal CA, WD to those interface units 60 that are located at a greater distance from the memory controller 200 or from the first interface unit 60 of the series arrangement (e.g., to the interface unit 60 which is assigned to the memory module 100c in FIG. 6).

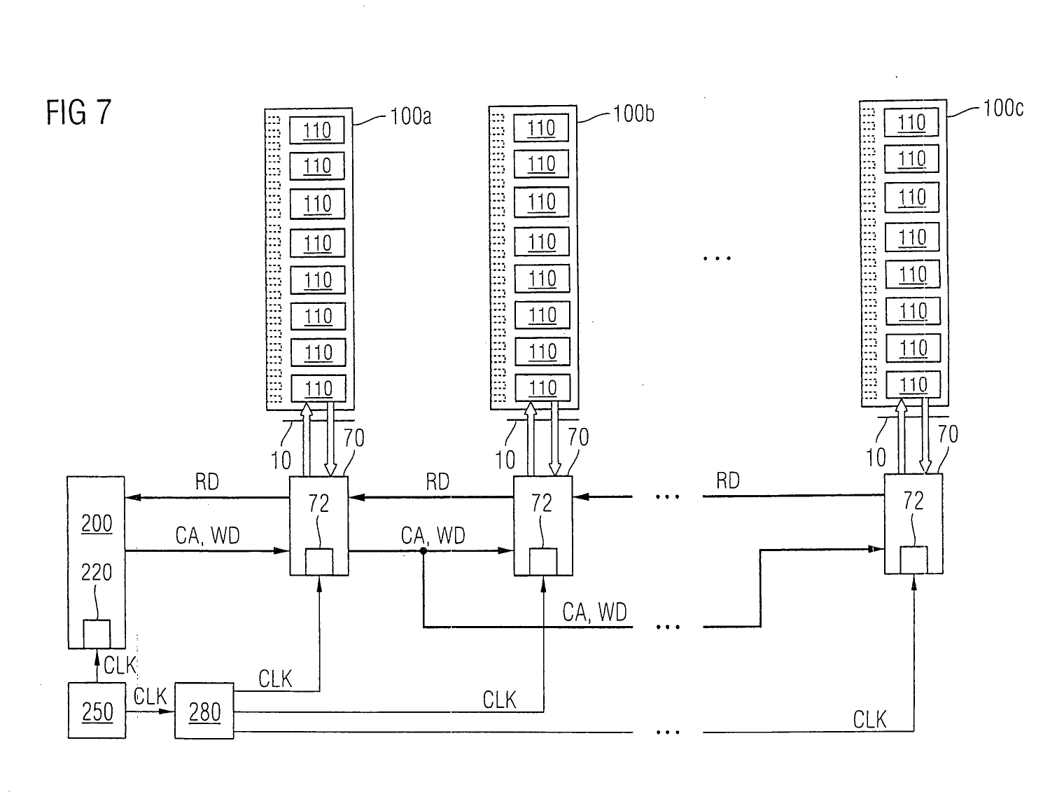

In the memory device embodiment illustrated in FIG. 6, the transfer of data is of the source-synchronous type (i.e., the associated clock signal CLK1 is transmitted in parallel to the command or write data signal CA, WD, and the associated clock signal CLK2 is transmitted in parallel to the read data signal RD). However, the star-type transfer of data according to the memory device embodiment of FIG. 6 can also be used in connection with a mesosynchronous data transfer, as has been explained with reference to the embodiments of FIGS. 3 and 5. This is illustrated in FIG. 7.

FIG. 7 illustrates a memory device according to one exemplary embodiment. As already mentioned, the memory device embodiment of FIG. 7 corresponds, in essence, to that of FIG. 6, but with the use of a mesosynchronous transfer of data corresponding to the structure explained with reference to FIG. 3. Accordingly, in the memory device embodiment of FIG. 7, the interface units 60 of the memory device embodiment of FIG. 6 have been replaced by interface units 70, which are designed for a mesosynchronous transfer of data with a star-type transmission of the command and write data signal CA, WD. In FIG. 7, components which correspond to those of FIGS. 2-6 are denoted by the same reference signs, and they are not explained further in the following.

The interface units 70 are each supplied with the reference clock signal RCLK generated by the clock replication means 280, the reference clock signal being generated centrally based on the main clock signal CLK generated by the phase locked loop 250.

In a manner similar to the memory device embodiment of FIG. 2, also the memory device embodiments of FIGS. 3-7 there is provided in each of the interface units 30, 40, 50, 60, 70 a phase locked loop 32, 42, 52, 62 and 72 respectively, which serves to condition input clock signals of the interface unit and to generate high-quality output clock signals. The structure of the interface units and the functioning of the phase locked loop contained therein is explained more fully in the following with reference to FIGS. 8-11.

FIG. 8 illustrates, in schematic form, one embodiment of a structure of an interface unit 20 in the memory device embodiment of FIG. 2. The interface unit 20 comprises, in addition to the phase locked loop 22, a first receiver RxP, for receiving the command or write data signal CA, WD from the memory controller 200 or from the preceding interface unit 20 of the series arrangement, and a first transmitter TxP, for transmitting the read data signal RD to the memory controller 200 or to the preceding interface unit 20 of the series arrangement. In addition, the interface unit 20 comprises a second receiver RxS, for receiving the read data signal RD from the next interface unit 20 of the series arrangement, and a second transmitter TxS, for transmitting the command data signal or write data signal CA, WD to the next interface unit 20 of the series arrangement 20. A bidirectional interface 25 is provided for communication with the memory module via the mechanically detachable connection 10.

As illustrated by FIG. 8, the phase locked loop 22 generates an input clock signal for the first transmitter TxP, and an input clock signal for the second transmitter TxS. Either the reference clock signal RCLK or the associated clock signal CLK1 of the command data signal or write data signal CA, WD can be selected, via a multiplexer 21, as an input clock signal of the phase locked loop 22. The associated clock signal CLK1 of the command or write data signal CA, WD serves as an input clock signal of the first receiver RxP. The associated clock signal CLK2 of the read data signal RD serves as an input clock signal of the second receiver RxS.

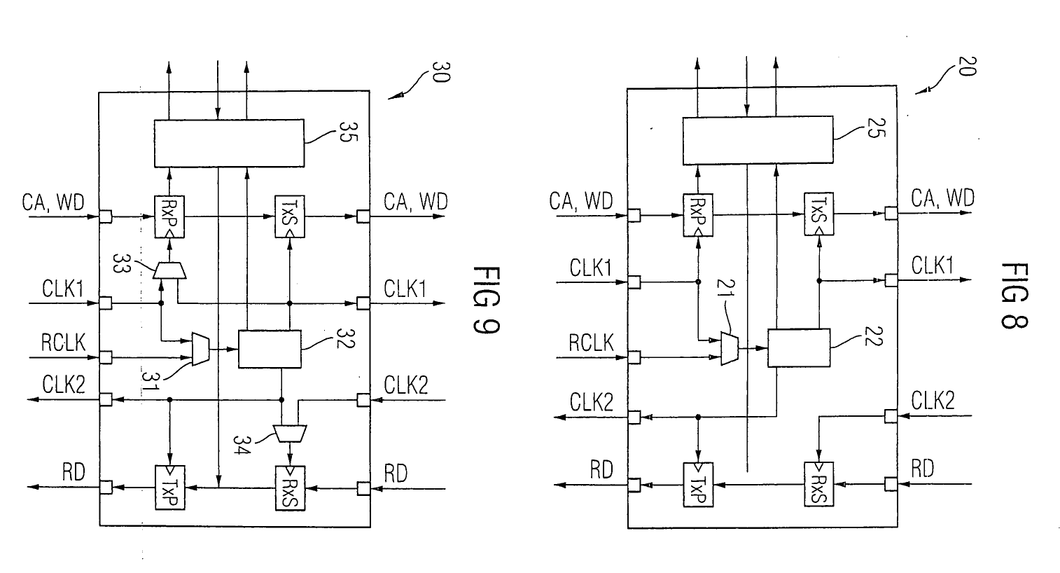

FIG. 9 illustrates, in schematic form, one embodiment of a structure of an interface unit 30 in the memory device embodiment of FIG. 3. The interface unit 30 comprises, in addition to the phase locked loop 32, a first receiver RxP, for receiving the command or write data signal CA, WD from the memory controller 200 or from the preceding interface unit 30 of the series arrangement, and a first transmitter TxP, for transmitting the read data signal RD to the memory controller 200 or to the preceding interface unit 30 of the series arrangement. In addition, the interface unit 30 comprises a second receiver RxS, for receiving the read data signal RD from the next interface unit 30 of the series arrangement, and a second transmitter TxS, for transmitting the command or write data signal CA, WD to the next interface unit 30 of the series arrangement 30. A bidirectional interface 35 is provided for communication with the memory module via the mechanically detachable connection 10.

As illustrated by FIG. 9, the phase locked loop 32 generates an input clock signal for the first transmitter TxP, and an input clock signal for the second transmitter TxS. Either the reference clock signal RCLK or the associated clock signal CLK1 of the command or write data signal CA, WD can be selected, via a multiplexer 31, as an input clock signal of the phase locked loop 32.

In contrast to the interface unit 20 embodiment of FIG. 8, the interface unit 30 embodiment of FIG. 9 comprises a first additional multiplexer 33, through which the input clock signal of the first receiver RxP can be selected between the associated clock signal CLK1 of the command or write data signal CA, WD and the output clock signal of the phase locked loop 32. Furthermore, the interface unit 30 comprises a second additional multiplexer 34, through which the input clock signal of the second receiver RxS can be selected between the associated clock signal CLK2 of the read data signal RD and the output clock signal of the phase locked loop 32.

In one embodiment, the multiplexers 31, 33 and 34 can thus be used to select, as the input clock signal of the first receiver RxP and of the second receiver RxS, an output clock signal of the phase locked loop 32, the output clock signal being generated based on the reference clock signal RCLK. The interface unit 30 can thereby be adapted to the mesosynchronous transfer of data represented in FIG. 3.

According to one embodiment, it is also possible to use an arrangement without the multiplexers 31, 33 and 34, the arrangement being designed exclusively for use in connection with a mesosynchronous transfer of data, in that the reference clock signal RCLK is used directly as an input clock signal of the phase locked loop 32 and the output clock signal of the phase locked loop 32 is used directly as an input clock signal of the first receiver RxP, of the second receiver RxS, of the first transmitter TxP and of the second transmitter TxS.

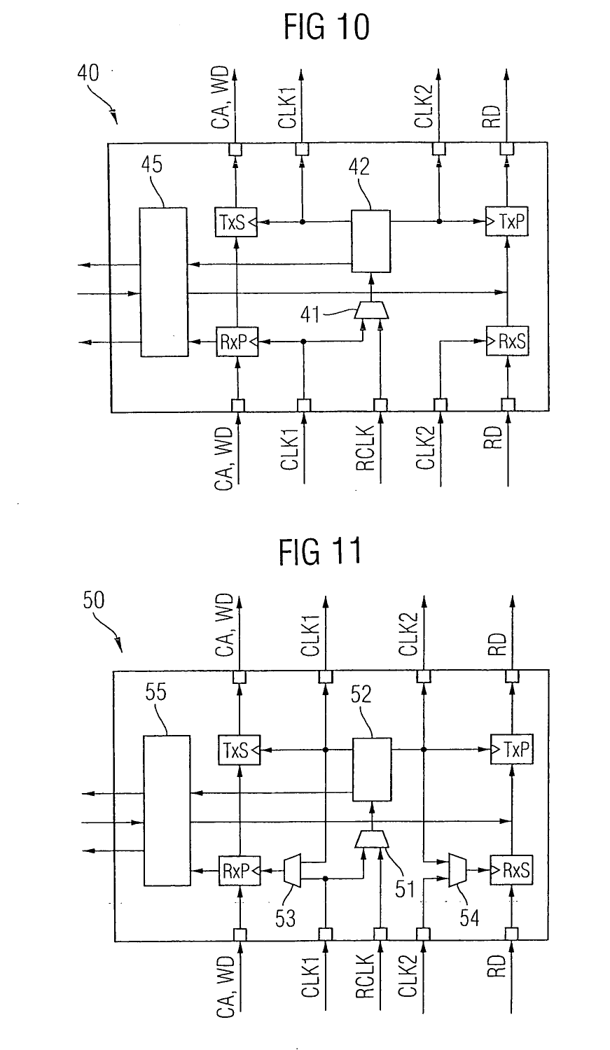

FIG. 10 illustrates, in schematic form, one embodiment of a structure of an interface unit 40 in the memory device embodiment of FIG. 4. The interface unit 40 comprises, in addition to the phase locked loop 42, a first receiver RxP, for receiving the command or write data signal CA, WD from the memory controller 200 or from the preceding interface unit 40 of the series arrangement, and a first transmitter TxP, for transmitting the read data signal RD to the memory controller 200 or to the next interface unit 40 of the series arrangement. In addition, the interface unit 40 comprises a second receiver RxS, for receiving the read data signal RD from the preceding interface unit 40 of the series arrangement, and a second transmitter TxS, for sending out the command data signal or write data signal CA, WD to the next interface unit 40 of the series arrangement. A bidirectional interface 45 is provided for communication with the memory module via the mechanically detachable connection 10.

The input clock signal of the first transmitter TxP and the input clock signal of the second transmitter TxS are constituted by an output clock signal of the phase locked loop 42. The input clock signal of the phase locked loop 42 can be selected, via a multiplexer 41, between the associated clock signal CLK1 of the command or write data signal CA, WD and the reference clock signal RCLK. The input clock signal of the first receiver RxP is constituted by the associated clock signal of the command or write data signal CA, WD. The input clock signal of the second receiver RxS is constituted by the associated clock signal CLK2 of the read data signal RD.

FIG. 11 illustrates, in schematic form, one embodiment of a structure of an interface unit 50 in the memory device embodiment of FIG. 5. The interface unit 50 comprises, in addition to the phase locked loop 52, a first receiver RxP, for receiving the command or write data signal CA, WD from the memory controller 200 or from the preceding interface unit 50 of the series arrangement, and a first transmitter TxP, for transmitting the read data signal RD to the memory controller 200 or to the next interface unit 50 of the series arrangement. In addition, the interface unit 50 comprises a second receiver RxS, for receiving the read data signal RD from the preceding interface unit 50 of the series arrangement, and a second transmitter TxS, for transmitting the command or write data signal CA, WD to the next interface unit 50 of the series arrangement. A bidirectional interface 55 is provided for communication with the memory module via the mechanically detachable connection 10.

The input clock signal of the first transmitter TxP and the input clock signal of the second transmitter TxS are constituted by an output clock signal of the phase locked loop 52. The input clock signal of the phase locked loop 52 can be selected, via a multiplexer 51, between the associated clock signal CLK1 of the command or write data signal CA, WD and the reference clock signal RCLK.

Furthermore, the interface unit 50 also comprises a first additional multiplexer 53, through which the input clock signal of the first receiver RxP can be selected between the associated clock signal CLK1 of the command or write data signal CA, WD and the output clock signal of the phase locked loop 52. Furthermore, the interface unit 50 comprises a second additional multiplexer 54, through which the input clock signal of the second receiver RxS can be selected between the associated clock signal CLK2 of the read data signal RD and the output clock signal of the phase locked loop 52.

By means of the multiplexers 51, 53 and 54, the interface unit 50 can be adapted to the mesosynchronous transfer of data represented in the memory device embodiment of FIG. 5, in that there is selected, as an input clock signal of the first receiver RxP and of the second receiver RxS, an output clock signal of the phase locked loop 52, the output clock signal being generated based on the reference clock signal RCLK in that this is selected, through the multiplexer 51, as an input clock signal of the phase locked loop 52. According to one embodiment, it is also possible for the interface unit 50 to be adapted exclusively to the mesosynchronous transfer of data, by dispensing with the multiplexers 51, 53 and 54, using the reference clock signal RCLK directly as an input clock signal of the phase locked loop 52, and using the output clock signal of the phase locked loop 52 directly as an input clock signal of the first receiver RxP, of the second receiver RxS, of the first transmitter TxP and of the second transmitter TxS.

The interface units 60 and 70 of the memory device embodiments of FIGS. 6 and 7 can have, in essence, the same structure as the interface units 20 and 30 of FIGS. 8 and 9 respectively. In this connection it is to be noted, however, that in this case the command or write data signal CA, WD need not be received from the preceding interface unit of the series arrangement. Rather, the input clock signal for interface units 60 or 70 which, in the series arrangement, are not disposed directly after the first interface unit 60 or 70, can also be received from the first interface unit 60 or 70 of the series arrangement.

According to one embodiment, the phase locked loops 22, 32, 42, 52, 62, 72 used in the interface units 20, 30, 40, 50, 60, 70 are digitally implemented. In one embodiment, it is thereby possible to achieve a high signal quality with a small amount of circuitry resource, and adaptation to further digital components of the interface units 20, 30, 40, 50, 60, 70 is facilitated. It is also possible, however, to use analog phase locked loops in the interface units, 20, 30, 40, 50, 60, 70 or for generating the main clock signal CLK.

It is to be understood that numerous modifications are possible in the above exemplary embodiments. For example, it is possible for the different forms of data transfer to be combined with one another. For example, source-synchronous data transfer and mesosynchronous data transfer can be combined with each other in one memory device. Furthermore, it is possible to combine the star-type transfer of the command or write data signal CA, WD, explained with reference to FIGS. 6 and 7, with a forward loop configuration according to FIG. 4 or 5.

Further, it is to be understood that in the above embodiments any illustrated or described connection or coupling between two functional blocks, devices, components or other physical or functional entities could also be implemented by indirect connection or coupling.

Accordingly, although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of transferring data in a memory device comprising at least one memory module and a memory controller, the method comprising:
coupling the memory module to the memory controller via a mechanically detachable data transfer connection;
transferring data between the memory controller and an interface unit assigned to the memory module and disposed on the same side of the mechanically detachable data transfer connection as the memory controller; and
transferring data between the interface unit and the memory module via the mechanically detachable data transfer connection.

2. The method according to claim 1, wherein the memory device comprises a plurality of memory modules each of which is assigned an interface unit, the method comprising:
transferring data between at least one of the interface units and another the interface units.

3. The method according to claim 2, wherein the interface units are coupled to one another in a series arrangement.

4. The method according to claim 3, comprising:
receiving a command or write data signal from the memory controller in a first interface unit of the series arrangement; and
transmitting the command or write data signal from the first interface unit to further interface units of the series arrangement.

5. The method according to claim 3, comprising:
receiving a command or write data signal from the memory controller in a first interface unit of the series arrangement; and
serially transmitting the command or write data signal from one of the interface units to a respective next interface unit of the series arrangement, starting from the first interface unit, until the command or write data signal is received in a final interface unit of the series arrangement.

6. The method according to claim 3, comprising:
serially transmitting a read data signal from one of the interface units to a respective preceding interface unit of the series arrangement, until the read data signal is received in a first interface unit of the series arrangement; and
transmitting the read data signal from the first interface unit of the series arrangement to the memory controller.

7. The method according to claim 3, comprising:
serially transmitting a read data signal from one of the interface units to a respective next interface unit of the series arrangement, until the read data signal is received in a final interface unit of the series arrangement; and
transmitting the read data signal from the final interface unit of the series arrangement to the memory controller.

8. The method according to claim 3, comprising:
transmitting a clock signal assigned to a command or write data signal in parallel to the command data signal or write data signal.

9. The method according to claim 8, comprising:
generating the clock signal assigned to the command data signal or write data signal with a phase locked loop.

10. The method according to claim 3, comprising:
transmitting a clock signal assigned to a read data signal in parallel to the read data signal.

11. The method according to claim 10, generating the clock signal assigned to the read data signal with a phase locked loop.

12. The method according to claim 1, comprising:
transmitting a reference clock signal to each of the interface units.

13. The method according to claim 12, comprising:
generating the reference clock signal with a phase locked loop.

14. A memory module comprising:
means for coupling to a memory controller of a memory device via a mechanically detachable data transfer connection;
means for receiving data from an external interface unit; and
means for transmitting data to the external interface unit, via the mechanically detachable data transfer connection.

15. The memory module according to claim 14, comprising:
at least one memory component configured to directly couple to the external interface unit via the mechanically detachable data transfer connection.

16. The memory module according to claim 14, wherein the mechanically detachable data transfer connection comprises a plug-in type connection.

17. A device configured to provide coupling between at least one memory module and a memory controller, the device comprising:
at least one interface unit, disposed on a same side of a mechanically detachable data transfer connection as the memory controller and coupled to the memory controller to transfer data, wherein the at least one interface unit is configured to provides coupling to the memory module to transfer data via the mechanically detachable data transfer connection.

18. The device according to claim 17,
wherein the device is configured to provide coupling of a plurality of memory modules to the memory controller; and
wherein the device comprises a plurality of interface units which are assigned to a respective detachable connection.

19. The device according to claim 18, wherein the interface units are coupled to one another in a series arrangement to transfer data.

20. The device according to claim 19, wherein only a first interface unit of the series arrangement is directly coupled to the memory controller to transfer data.

21. The device according to claim 18, wherein the interface units each comprise:
a first receiver configured to receive a command or write data signal from the memory controller or from a first further interface unit;
a first transmitter configured to transmit a read data signal to the memory controller or to the first further interface unit;
a second receiver configured to receive the read data signal from a second further interface unit; and
a second transmitter configured to transmit the command data signal or write data signal to the second further interface unit.

22. The device according to claim 21, wherein the interface units each comprise a phase locked loop configured to generate an input clock signal for the first transmitter and for the second transmitter.

23. The device according to claim 22, wherein the phase lock loop in each interface unit is configured to generate an input clock signal of the first receiver or of the second receiver.

24. The device according to claim 17, comprising:
a phase locked loop configured to generate a main clock signal.

25. The device according to claim 17, wherein the at least one interface unit comprises a bidirectional interface configured to provide connection to the memory module via the mechanically detachable data transfer connection.

26. The device according to claim 17, wherein the at least one interface unit is configured to communicate with the memory controller and/or with a further interface unit according to a serial high-speed protocol.

27. The device according to claim 17, wherein the device is provided on a system board of a computer system.

28. A memory device, comprising:
a memory controller;
at least one memory module coupled to the memory controller via a mechanically detachable data transfer connection; and
at least one interface unit disposed on the same side of the mechanically detachable data transfer connection as the memory controller and coupled to the memory controller to transfer data, wherein the at least one interface unit is configured to provide coupling to the memory module to transfer data via the mechanically detachable data transfer connection.

29. The memory device according to claim 28, wherein the interface unit is provided on a system board of a computer system.

30. The memory device according to claim 29, wherein the system board includes a receptacle to receive the memory module.

31. The memory device according to claim 28, wherein the interface unit communicates with the memory controller and/or with a further interface unit according to a serial high-speed protocol.

32. The memory device according to claim 28, comprising:
a plurality of memory modules; and
a plurality of interface units, each interface unit provided for a corresponding one of the memory modules.

33. The memory device according to claim 32, wherein the plurality of interface units are connected in a chain arrangement.
